(19) United States
(12) Patent Application Publication
(10) Pub. No.: US 2025/0246534 A1
(43) Pub. Date: Jul. 31, 2025

(54) SEMICONDUCTOR DEVICE

(71) Applicant: Rohm Co., Ltd., Kyoto-shi (JP)

(72) Inventor: Kenichi YOSHIMOCHI, Kyoto-shi (JP)

(21) Appl. No.: 19/071,162

(22) Filed: Mar. 5, 2025

Related U.S. Application Data
(63) Continuation of application No. PCT/JP2023/029164, filed on Aug. 9, 2023.

(30) Foreign Application Priority Data
Sep. 9, 2022 (JP) 2022-143827

(51) Int. Cl. H01L 23/498; H01L 23/00; H01L 23/495; H01L 25/07; H10D 80/20

(52) U.S. Cl. CPC H01L 23/49838; H01L 23/49503; H01L 23/49562; H01L 25/072; H10D 80/251; H01L 24/32; H01L 2224/32245; H01L 2924/1033; H01L 2924/13064

(57) ABSTRACT

A semiconductor device includes a first semiconductor element, a second semiconductor element, a first conductive member, and a second conductive member. The first semiconductor element includes a first drain electrode and a first drain electrode on a first side in a first direction. The second semiconductor element includes a second drain electrode and a second source electrode on the first side in the first direction, and the second semiconductor element is next to the first semiconductor element in a second direction perpendicular to the first direction. The first conductive member is electrically bonded to the first drain electrode and the second drain electrode. The second conductive member is electrically bonded to the first source electrode and the second source electrode. The first conductive member and the second conductive member each intersect a gap between the first semiconductor element and the second semiconductor element as viewed in the first direction.

### TECHNICAL FIELD

The present disclosure relates to semiconductor devices.

### BACKGROUND ART

JP-A-2020-115524 discloses an example of a semiconductor device incorporating a laterally-structured semiconductor element (HEMT). The semiconductor element is bonded to a first lead. The semiconductor element includes a first electrode corresponding to a source, and a third electrode corresponding to a drain. The first electrode is electrically connected by a wire to a second lead, which is adjacent to the first lead. The third electrode is electrically connected by a wire to a third lead, which is adjacent to the first lead.

Notably, the semiconductor device of JP-A-2020-115524 incorporates a single semiconductor element. Thus, the semiconductor device may not be able to carry a larger electric current unless the internal structure of the semiconductor element is modified. However, such modifications to increase the current-carrying capacity may cause degradation in the performance of the semiconductor element, which, in turn, will degrade the overall performance of the semiconductor device.

### BRIEF DESCRIPTION OF THE DRAWINGS

FIG. 1 is a plan view of a semiconductor device according to a first embodiment of the present disclosure, with a sealing resin shown as transparent.

FIG. 2 is a plan view corresponding to FIG. 1, omitting a first conductive member and a second conductive member.

FIG. 3 is a bottom view of the semiconductor device shown in FIG. 1.

FIG. 4 is a front view of the semiconductor device shown in FIG. 1.

FIG. 5 is a rear view of the semiconductor device shown in FIG. 1.

FIG. 6 is a right-side view of the semiconductor device shown in FIG. 1.

FIG. 7 is a left-side view of the semiconductor device shown in FIG. 1.

FIG. 8 is a sectional view taken along line VIII-VIII in FIG. 1.

FIG. 9 is a sectional view taken along line IX-IX in FIG. 1.

FIG. 10 is a sectional view taken along line X-X in FIG. 1.

FIG. 11 is a sectional view taken along line XI-XI in FIG. 1.

FIG. 12 is a plan view of a semiconductor device according to a second embodiment of the present disclosure, omitting a sealing resin.

FIG. 13 is a sectional view taken along line XIII-XIII in FIG. 12.

FIG. 14 is a sectional view taken along line XIV-XIV in FIG. 12.

FIG. 15 is a plan view of a semiconductor device according to a third embodiment of the present disclosure, omitting a sealing resin.

FIG. 16 is a plan view corresponding to FIG. 15, with a first semiconductor element, a second semiconductor element, a third semiconductor element, a fourth semiconductor element, and an IC shown as transparent.

FIG. 17 is a bottom view of the semiconductor device shown in FIG. 15.

FIG. 18 is a sectional view taken along line XVIII-XVIII in FIG. 16.

FIG. 19 is a sectional view taken along line XIX-XIX in FIG. 16.

FIG. 20 is a sectional view taken along line XX-XX in FIG. 16.

FIG. 21 is a sectional view taken along line XXI-XXI in FIG. 16.

FIG. 22 is a sectional view taken along line XXII-XXII in FIG. 16.

### DETAILED DESCRIPTION OF EMBODIMENTS

The following specifically describes preferred embodiments of the present disclosure with reference to the accompanying drawings.

### First Embodiment

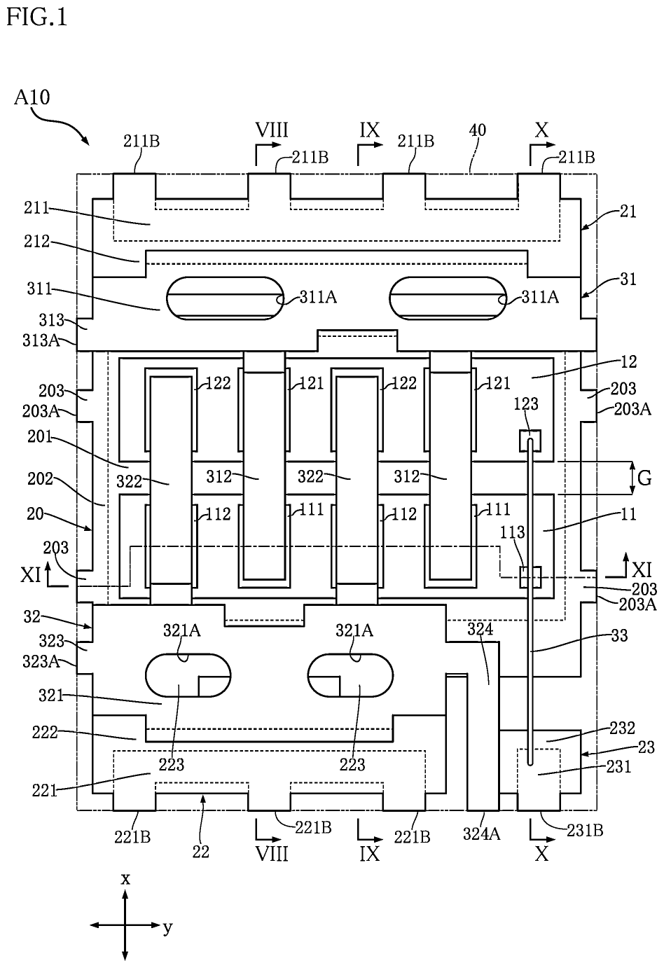

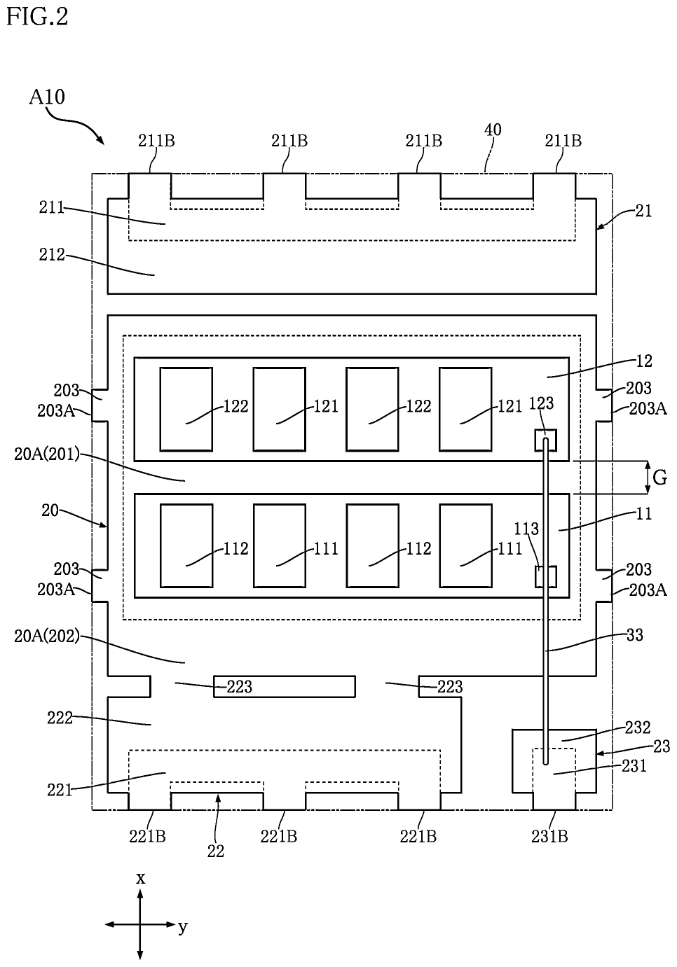

With reference to FIGS. 1 to 11, the following describes a semiconductor device A10 according to a first embodiment of the present disclosure. The semiconductor device A10 is typically found in power conversion circuits, such as DC-DC converters and inverters. The semiconductor device A10 is in a QFN (quad flat non-leaded) package. The semiconductor device A10 includes a first semiconductor element 11, a second semiconductor element 12, a die pad 20, a first lead 21, a second lead 22, a third lead 23, a first conductive member 31, a second conductive member 32, a third conductive member 33, and a sealing resin 40. For the convenience of description, FIG. 1 shows the sealing resin 40 as transparent. Similarly, FIG. 2 omits the first conductive member 31 and the second conductive member 32 from FIG. 1. FIG. 1 shows the outline of the sealing resin 40 by an imaginary line (dash-double dot line).

In the description of the semiconductor device A10, the direction of the normal to a mounting surface 20A of the die pad 20 described later is referred to as “first direction z”. A direction perpendicular to the first direction z is referred to as “second direction x”. The direction perpendicular to both the first direction z and second direction x is referred to as “third direction y”.

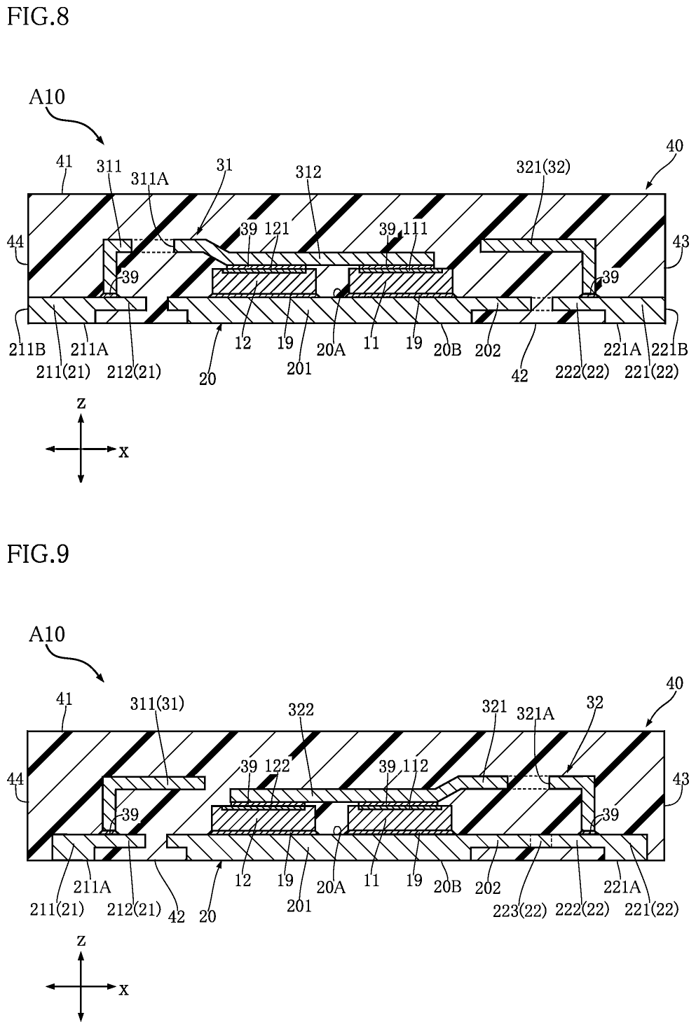

As shown in FIGS. 8 to 10, the sealing resin 40 covers the first semiconductor element 11, the second semiconductor element 12, the first conductive member 31, the second conductive member 32, and the third conductive member 33. The sealing resin 40 also covers a portion of each of the die pad 20, the first lead 21, the second lead 22, and the third lead 23. The scaling resin 40 is electrically insulating. The sealing resin 40 is made of a material containing a black epoxy resin, for example. The sealing resin 40 has a top surface 41, a bottom surface 42, a first side surface 43, a second side surface 44, and two third side surfaces 45.

As shown in FIGS. 8 to 11, the top surface 41 faces the same side in the first direction z as the mounting surface 20A of the die pad 20, which will be described later. The bottom surface 42 faces away from the top surface 41 in the first direction z.

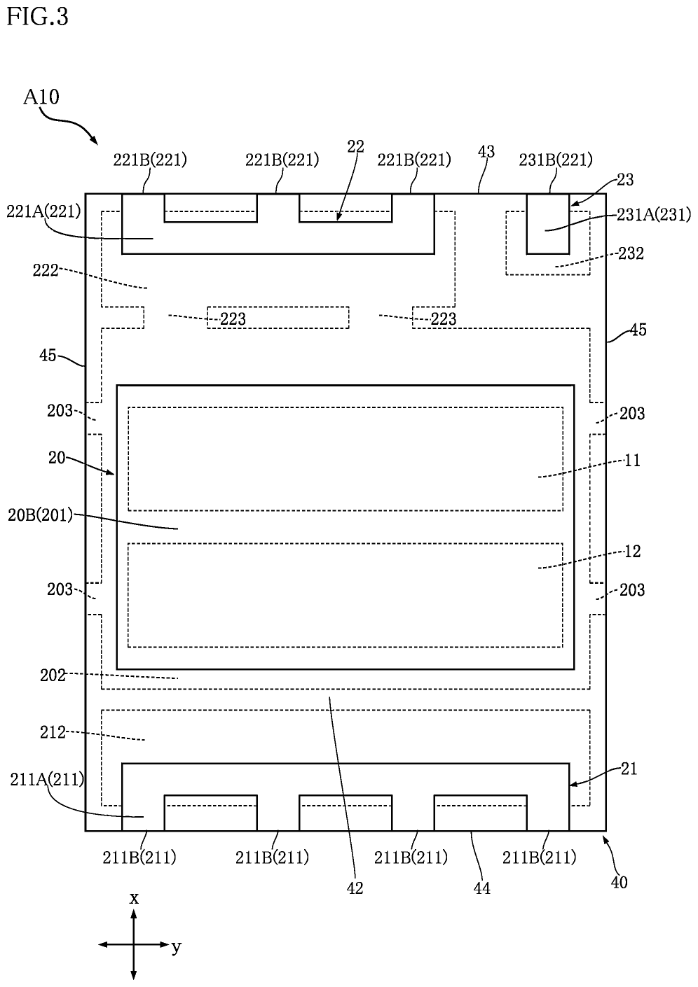

As shown in FIG. 3, the first side surface 43 and the second side surface 44 face away from each other in the second direction x. The first side surface 43 and the second side surface 44 are located opposite to each other with respect to the die pad 20. The two third side surfaces 45 face away from each other in the third direction y. The two third side surfaces 45 are located opposite to each other with respect to the die pad 20.

As shown in FIG. 2, the die pad 20 is located between the first lead 21 and the second lead 22 in the second direction x. The die pad 20 is formed from the same lead frame as the first lead 21, the second lead 22, and the third lead 23. Hence, the die pad 20, the first lead 21, the second lead 22, and the third lead 23 are all made of the same metal material. As shown in FIGS. 2 and 3, the die pad 20 has the mounting surface 20A, a reverse surface 20B, a mounting part 201, an overhanging part 202, and a plurality of suspending parts 203. The mounting surface 20A and the reverse surface 20B face away from each other in the first direction z. The mounting surface 20A faces the first semiconductor element 11 and the second semiconductor element 12. As shown in FIG. 3, the reverse surface 20B is exposed from the bottom surface 42 of the sealing resin 40.

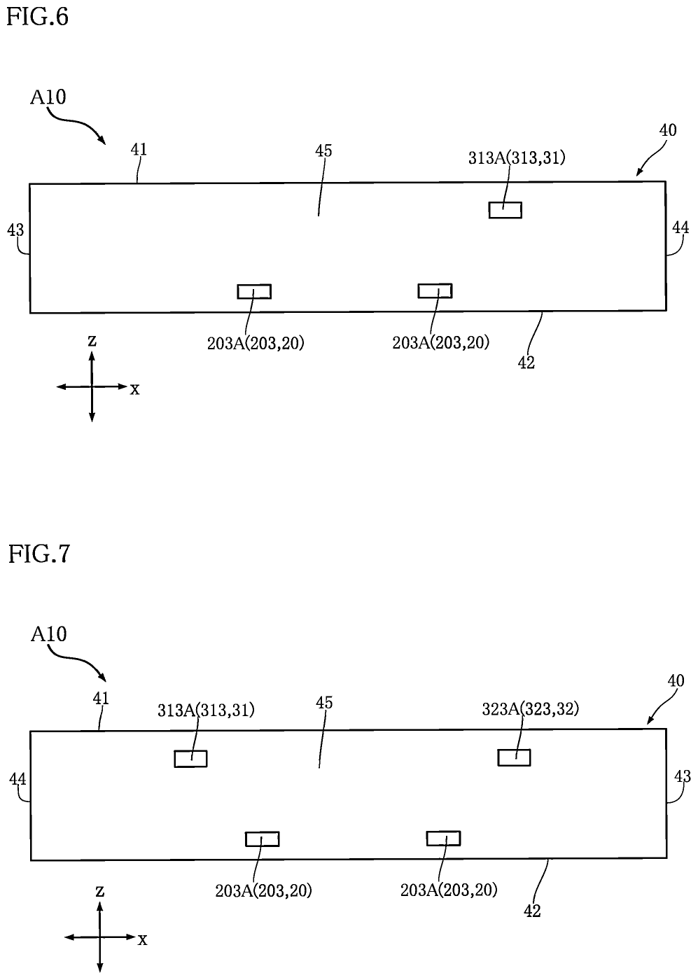

As shown in FIGS. 8 to 11, the mounting part 201 includes the mounting surface 20A and the reverse surface 20B and overlaps with the entire reverse surface 20B as viewed in the first direction z. The mounting part 201 has the first semiconductor element 11 and the second semiconductor element 12 mounted thereon. The overhanging part 202 extends from the mounting part 201 in a direction perpendicular to the first direction z. The overhanging part 202 includes the mounting surface 20A and is spaced apart from the bottom surface 42 of the scaling resin 40. As shown in FIG. 2, the overhanging part 202 surrounds the mounting part 201 as viewed in the first direction z. The overhanging part 202 is sandwiched between portions of the scaling resin 40 in the first direction z. The suspending parts 203 each extend from the overhanging part 202 in the third direction y. Each suspending part 203 has an end surface 203A facing in the third direction y. As shown in FIGS. 6 and 7, the end surface 203A of each suspending part 203 is exposed from one of the two third side surfaces 45 of the scaling resin 40.

As shown in FIGS. 8 and 9, the first semiconductor element 11 and the second semiconductor element 12 are electrically bonded to the mounting surface 20A of the die pad 20 each via a bonding layer 19. The bonding layer 19 is solder, for example. The first semiconductor element 11 and the second semiconductor element 12 are transistors (switching elements) mainly used for power conversion. The first semiconductor element 11 and the second semiconductor element 12 are made of a material containing a nitride semiconductor. For the semiconductor device A10, the first semiconductor element 11 and the second semiconductor element 12 are high electron mobility transistors (HEMTs) made of a material containing gallium nitride (GaN).

As shown in FIG. 2, the first semiconductor element 11 includes two first drain electrodes 111, two first source electrodes 112, and a first gate electrode 113. The two first drain electrodes 111, the two first source electrodes 112, and the first gate electrode 113 are located on the side opposite the mounting surface 20A of the die pad 20 in the first direction z. The electric current corresponding to the power to be converted by the first semiconductor element 11 flows through the two first drain electrodes 111. The electric current corresponding to the power having been converted by the first semiconductor element 11 flows through the two first source electrodes 112. A gate voltage for driving the first semiconductor element 11 is applied to the first gate electrode 113. The first semiconductor element 11 has a greater dimension in the third direction y than in the second direction x.

As shown in FIG. 2, each first source electrode 112 is next to a first drain electrode 111 in the third direction y. The first gate electrode 113 is located on a side in the third direction y from the two first drain electrodes 111 and the two first source electrodes 112.

As shown in FIG. 2, the second semiconductor element 12 is adjacent to the first semiconductor element 11 in the second direction x. The first semiconductor element 11 and the second semiconductor element 12 are separated by a gap G in the second direction x. The second semiconductor element 12 includes two second drain electrodes 121, two second source electrodes 122, and a second gate electrode 123. The second drain electrodes 121, the second source electrodes 122, and the second gate electrode 123 are located on the side opposite the mounting surface 20A of the die pad 20 in the first direction z. The electric current corresponding to the power to be converted by the second semiconductor element 12 flows through the two second drain electrodes 121. The electric current corresponding to the power having been converted by the second semiconductor element 12 flows through the two second source electrodes 122. A gate voltage for driving the second semiconductor element 12 is applied to the second gate electrode 123. The second semiconductor element 12 has a greater dimension in the third direction y than in the second direction x.

As shown in FIG. 2, each second source electrode 122 is adjacent to a second drain electrode 121 in the third direction y. Each second drain electrode 121 is adjacent to a first drain electrode 111 of the first semiconductor element 11 in the second direction x. Each second source electrode 122 is adjacent to a first source electrode 112 of the first semiconductor element 11 in the second direction x.

As shown in FIG. 2, the second gate electrode 123 is located on a side in the third direction y from the two second drain electrodes 121 and the two second source electrodes 122. The second gate electrode 123 is adjacent to the first gate electrode 113 of the first semiconductor element 11 in the second direction x.

As shown in FIG. 2, the first lead 21 is located opposite the second lead 22 and the third lead 23 in the second direction x with respect to the die pad 20. As shown in FIG. 3, the first lead 21 is closer to the second side surface 44 of the sealing resin 40 than to the first side surface 43 of the scaling resin 40.

As shown in FIGS. 2 and 3, the first lead 21 includes a first terminal part 211 and a first overhanging part 212. The first terminal part 211 has a mounting surface 211A and a plurality of side surfaces 211B. The mounting surface 211A faces the same side as the bottom surface 42 of the sealing resin 40 in the first direction z. The mounting surface 211A is exposed from the bottom surface 42. The plurality of side surfaces 211B each face the same side as the second side surface 44 of the sealing resin 40 in the second direction x. The side surfaces 211B are each exposed from the second side surface 44. The first overhanging part 212 extends from the first terminal part 211 in a direction perpendicular to the first direction z. The first overhanging part 212 is spaced apart from the bottom surface 42. The first overhanging part 212 is sandwiched between portions of the sealing resin 40 in the first direction z.

As shown in FIG. 2, the second lead 22 is spaced apart from the first lead 21 in the second direction x. As shown in FIG. 3, the second lead 22 is closer to the first side surface 43 of the scaling resin 40 than to the second side surface 44 of the scaling resin 40.

As shown in FIGS. 2 and 3, the second lead 22 includes a second terminal part 221, a second overhanging part 222, and two coupling parts 223. The second terminal part 221 has a mounting surface 221A and a plurality of side surfaces 221B. The mounting surface 221A faces the same side as the bottom surface 42 of the sealing resin 40 in the first direction z. The mounting surface 221A is exposed from the bottom surface 42. The plurality of side surfaces 221B each face the same side as the first side surface 43 of the scaling resin 40 in the second direction x. The side surfaces 221B are exposed from the first side surface 43. The second overhanging part 222 extends from the second terminal part 221 in a direction perpendicular to the first direction z. The second overhanging part 222 is spaced apart from the bottom surface 42. The second overhanging part 222 is sandwiched between portions of the sealing resin 40 in the first direction Z. The two coupling parts 223 each extend from the second overhanging part 222 in the second direction x. The two coupling parts 223 are spaced apart from each other in the third direction y. Each coupling part 223 connects the second overhanging part 222 to the overhanging part 202 of the die pad 20. Thus, the second lead 22 is electrically connected to the die pad 20. Each coupling part 223 is sandwiched between portions of the sealing resin 40 in the first direction z.

As shown in FIG. 2, the third lead 23 is adjacent to the second lead 22 in the third direction y. As shown in FIG. 3, the third lead 23 is closer to the first side surface 43 of the sealing resin 40 than to the second side surface 44 of the sealing resin 40.

As shown in FIGS. 2 and 3, the third lead 23 includes a third terminal part 231 and a third overhanging part 232. The third terminal part 231 has a mounting surface 231A and a side surface 231B. The mounting surface 231A faces the same side as the bottom surface 42 of the scaling resin 40 in the first direction z. The mounting surface 231A is exposed from the bottom surface 42. The side surface 231B faces the same side as the first side surface 43 of the scaling resin 40 in the second direction x. The side surface 231B is exposed from the first side surface 43. The third overhanging part 232 extends from the third terminal part 231 in a direction perpendicular to the first direction z. The third overhanging part 232 is spaced apart from the bottom surface 42. The third overhanging part 232 is sandwiched between portions of the sealing resin 40 in the first direction z.

As shown in FIGS. 1 and 8, the first conductive member 31 is electrically bonded to the two first drain electrodes 111 of the first semiconductor element 11 and the two second drain electrodes 121 of the second semiconductor element 12 via a bonding layer 39. The bonding layer 39 is solder, for example. For the semiconductor device A10, the first conductive member 31 is a metal clip. The first conductive member 31 is formed from the same lead frame as the second conductive member 32. Hence, the first conductive member 31 and the second conductive member 32 are made of the same metal material. Note that the lead frame for forming the first conductive member 31 is different from the one for forming the die pad 20.

As shown in FIG. 1, the first conductive member 31 includes a first base part 311, two first connecting parts 312, and two suspending parts 313. The first base part 311 is located opposite the first semiconductor element 11 in the second direction x with respect to the second semiconductor element 12. As shown in FIG. 8, the first base part 311 is electrically bonded to the first overhanging part 212 of the first lead 21 via the bonding layer 39. Thus, the two first drain electrodes 111 of first semiconductor element 11 and the two second drain electrodes 121 of the second semiconductor element 12 are electrically connected to the first lead 21. The first base part 311 has two through-holes 311A. The two through-holes 311A are spaced apart from each other in the third direction y. The two through-holes 311A each penetrate the first base part 311 in the first direction z.

As shown in FIG. 1, the two first connecting parts 312 are connected to the first base part 311. The two first connecting parts 312 are spaced apart from each other in the third direction y. The two first connecting parts 312 each extend in the second direction x as viewed in the first direction z. As shown in FIG. 8, each first connecting part 312 is electrically bonded to one first drain electrode 111 of the first semiconductor element 11 via the bonding layer 39. Each first connecting part 312 is also electrically bonded to one second drain electrode 121 of the second semiconductor element 12 via the bonding layer 39. As viewed in the first direction z, each first connecting part 312 intersects the gap G between the first semiconductor element 11 and the second semiconductor element 12.

As shown in FIG. 1, the two suspending parts 313 each extend from the first base part 311 in the third direction y. The two suspending parts 313 are located opposite to each other in the third direction y with respect to the first base part 311. Each suspending part 313 has an end surface 313A facing in the third direction y. As shown in FIGS. 6 and 7, the end surface 313A of each suspending part 313 is exposed from one of the two third side surfaces 45 in the sealing resin 40.

As shown in FIGS. 1 and 9, the second conductive member 32 is electrically bonded to the two first source electrodes 112 of the first semiconductor element 11 and the two second source electrodes 122 of the second semiconductor element 12 via the bonding layer 39. For the semiconductor device A10, the second conductive member 32 is a metal clip.

As shown in FIG. 1, the second conductive member 32 includes a second base part 321, two second connecting parts 322, a suspending part 323, and an arm part 324. The second base part 321 is located opposite the first base part 311 of the first conductive member 31 in the second direction x with respect to the first semiconductor element 11 and the second semiconductor element 12. As shown in FIG. 9, the second base part 321 is electrically bonded to the second overhanging part 222 of the second lead 22 via the bonding layer 39. Thus, the two first source electrodes 112 of the first semiconductor element 11 and the two second source electrodes 122 of the second semiconductor element 12 are electrically connected to the second lead 22. The second base part 321 has two through-holes 321A. The two through-holes 321A are spaced apart from each other in the third direction y. The two through-holes 321A each penetrate the second base part 321 in the first direction z.

As shown in FIG. 1, the two second connecting parts 322 are connected to the second base part 321. The two second connecting parts 322 are spaced apart from each other in the third direction y. The two second connecting parts 322 each extend in the second direction x as viewed in the first direction z. As shown in FIG. 9, each second connecting part 322 is electrically bonded to one first source electrode 112 of the first semiconductor element 11 via the bonding layer 39. Each second connecting part 322 is also electrically bonded to one second source electrode 122 of the second semiconductor element 12 via the bonding layer 39. As viewed in the first direction z, each second connecting part 322 intersects the gap G between the first semiconductor element 11 and the second semiconductor element 12.

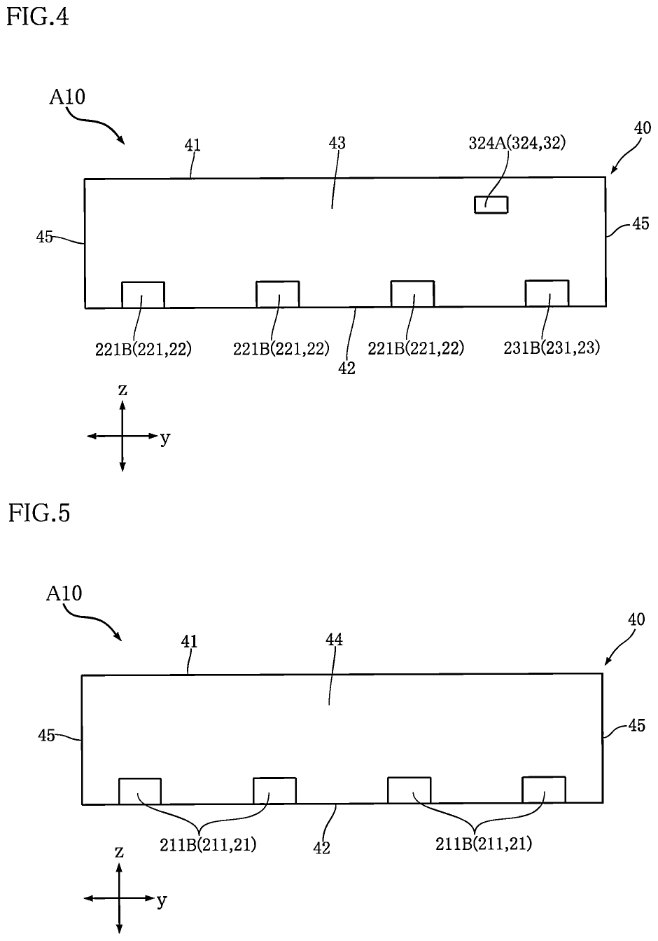

As shown in FIG. 1, the suspending part 323 and the arm part 324 are located opposite to each other in the third direction y with respect to the second base part 321. The suspending part 323 extends from the second base part 321 in the third direction y. The suspending part 323 has an end surface 323A facing in the third direction y. As shown in FIG. 7, the end surface 323A is exposed from one of the two third side surfaces 45 of the sealing resin 40. The arm part 324 includes a portion extending in the third direction y from the second base part 321 and a portion extending therefrom in the second direction x. The arm part 324 has an end surface 324A facing in the second direction x. As shown in FIG. 4, the end surface 324A is exposed from the first side surface 43 of the scaling resin 40.

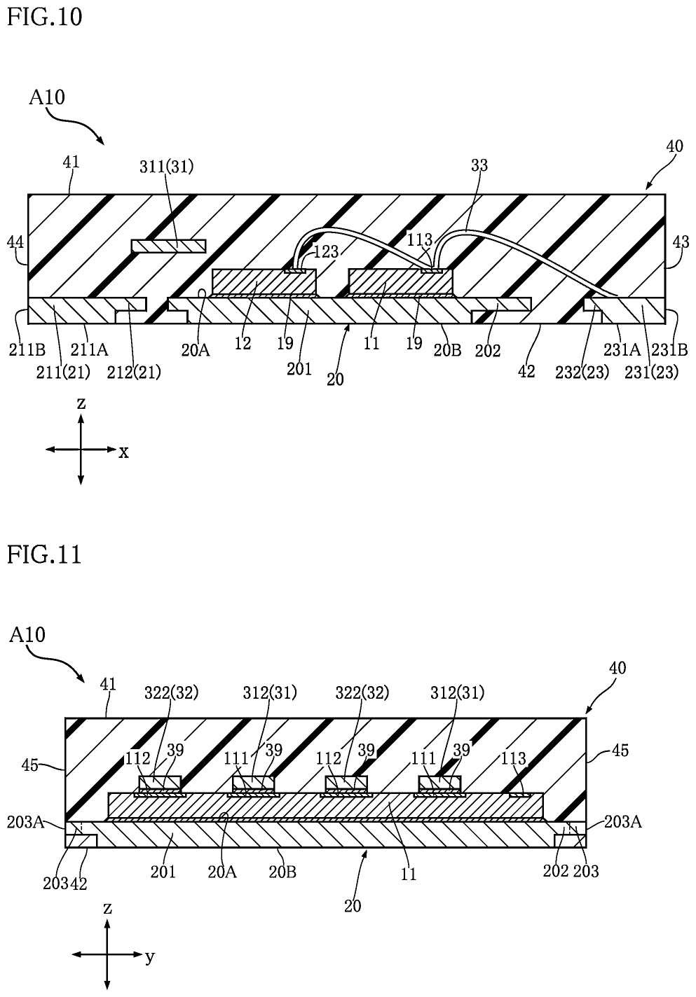

As shown in FIGS. 1 and 10, the third conductive member 33 is electrically bonded to the first gate electrode 113 of the first semiconductor element 11, the second gate electrode 123 of the second semiconductor element 12, and the third lead 23. The third conductive member 33 is a wire. Thus, the third conductive member 33 is electrically bonded by wire bonding to the first gate electrode 113, the second gate electrode 123, and the third lead 23. As viewed in the first direction z, the third conductive member 33 extends in the second direction x. As viewed in the first direction z, the third conductive member 33 is spaced apart from the two first drain electrodes 111 of the first semiconductor element 11, the two second drain electrodes 121 of the second semiconductor element 12, the first conductive member 31, and the second conductive member 32.

The following describes the operation and effects of the semiconductor device A10.

A semiconductor device A10 includes: a first semiconductor element 11 that includes a first drain electrode 111 and a first source electrode 112; a second semiconductor element 12 that includes a second drain electrode 121 and a second source electrode 122; a first conductive member 31; and a second conductive member 32. The first conductive member 31 is electrically bonded to the first drain electrode 111 and the second drain electrode 121. The second conductive member 32 is electrically bonded to the first source electrode 112 and the second source electrode 122. As viewed in the first direction z, the first conductive member 31 and the second conductive member 32 each intersect a gap G existing between the first semiconductor element 11 and the second semiconductor element 12. With this configuration, the first drain electrode 111 and the second drain electrode 121 are connected in parallel to the first conductive member 31. Additionally, the first source electrode 112 and the second source electrode 122 are connected in parallel to the second conductive member 32. This enables the semiconductor device A10 to carry a larger electric current. In addition, even if the function of the first semiconductor element 11 degrades, the semiconductor device A10 remains operational as long as the second semiconductor element 12 functions normally. The semiconductor device A10 is thus capable of carrying a larger electric current, while ensuring greater reliability.

The second drain electrode 121 of the second semiconductor element 12 is adjacent to the first drain electrode 111 of the first semiconductor element 11 in the second direction x. The first conductive member 31 includes a first base part 311 and a first connecting part 312 connected to the first base part 311. As viewed in the first direction z, the first connecting part 312 extends in the second direction x. The first connecting part 312 is electrically bonded to the first drain electrode 111 and the second drain electrode 121. This configuration ensures that the conductive path length of the first conductive member 31 is shorter, while avoiding an increase in the size of the first semiconductor element 11 and the second semiconductor element 12.

The second source electrode 122 of the second semiconductor element 12 is adjacent to the first source electrode 112 of the first semiconductor element 11 in the second direction x. The second conductive member 32 includes a second base part 321 and a second connecting part 322 connected to the second base part 321. As viewed in the first direction z, the second connecting part 322 extends in the second direction x. The second connecting part 322 is electrically bonded to the first source electrode 112 and the second source electrode 122. This configuration ensures that the conductive path length of the second conductive member 32 is shorter, while avoiding an increase in the size of the first semiconductor element 11 and the second semiconductor element 12.

The first semiconductor element 11 includes a first gate electrode 113. The second semiconductor element 12 includes a second gate electrode 123 at a location adjacent to the third semiconductor element 13 in the second direction x. The semiconductor device A10 further includes a third conductive member 33 electrically bonded to the first gate electrode 113 and the second gate electrode 123. As viewed in the first direction z, the third conductive member 33 extends in the second direction x. This configuration ensures that the conductive path length of the third conductive member 33 is shorter, while avoiding an increase in the size of the first semiconductor element 11 and the second semiconductor element 12.

As viewed in the first direction z, the third conductive member 33 is spaced apart from the first conductive member 31 and the second conductive member 32. This configuration allows, in the manufacture of the semiconductor device A10, the third conductive member 33 to be easily bonded after the first conductive member 31 and the second conductive member 32, because the bonding is not obstructed by the first conductive member 31 and the second conductive member 32.

The semiconductor device A10 includes: a die pad 20 to which the first semiconductor element 11 and the second semiconductor element 12 are bonded; and a sealing resin 40 covering the first semiconductor element 11 and the second semiconductor element 12. The die pad 20 is exposed from the bottom surface 42 of the scaling resin 40. This configuration improves the heat dissipation of the semiconductor device A10.

The semiconductor device A10 further includes: a first lead 21 to which the first conductive member 31 is electrically bonded; a second lead 22 to which the second conductive member 32 is electrically bonded, and a third lead 23 to which the third conductive member 33 is electrically bonded. The sealing resin 40 includes a first side surface 43 and a second side surface 44 facing away from each other in the second direction x. The first lead 21, the second lead 22, and the third lead 23 are each exposed from either the first side surface 43 or the second side surface 44. This configuration ensures that a greater volume of solder adheres to each of the first lead 21, the second lead 22, and the third lead 23 when the semiconductor device A10 is mounted to a wiring board. Thus, the semiconductor device A10 is more strongly bonded to the wiring board.

### Second Embodiment

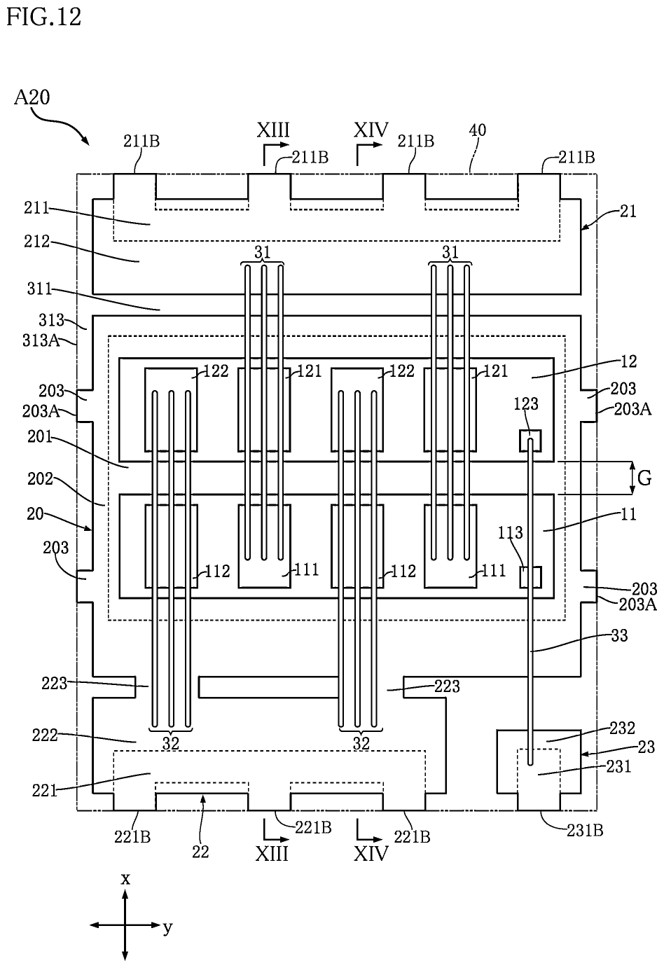

With reference to FIGS. 12 to 14, the following describes a semiconductor device A20 according to a second embodiment of the present disclosure. In these figures, the elements that are identical or similar to those of the semiconductor device A10 described above are indicated by the same reference numerals, and overlapping descriptions are omitted. For the convenience of description, FIG. 12 omits the sealing resin 40.

The semiconductor device A20 differs from the semiconductor device A10 in the configurations of the first conductive member 31 and the second conductive member 32.

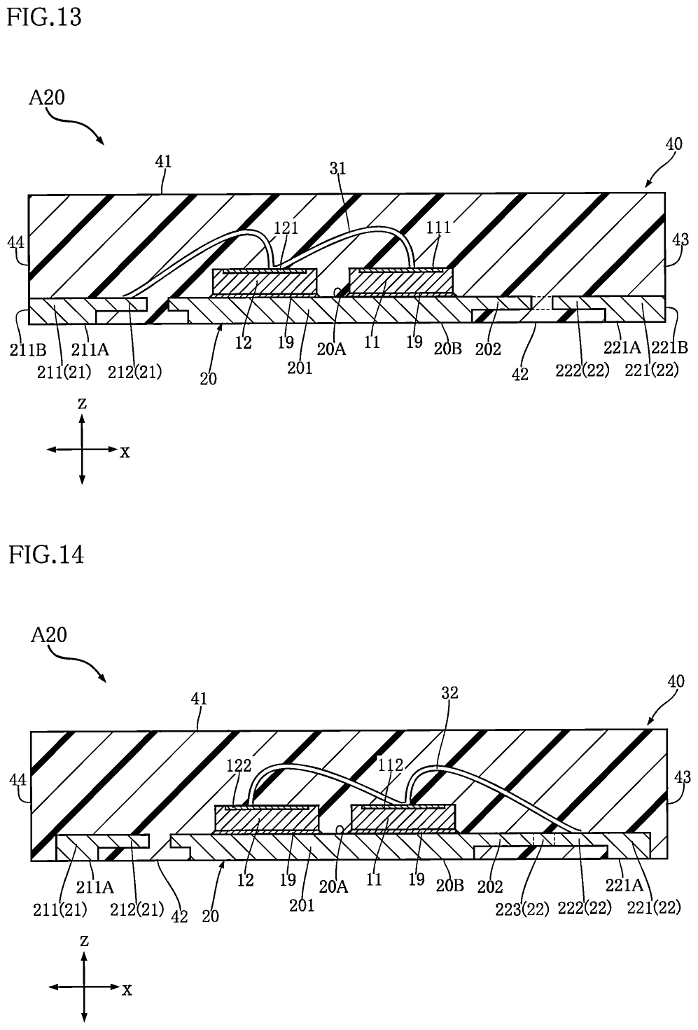

As shown in FIGS. 12 and 13, the first conductive member 31 is a plurality of wires. The first conductive member 31 is electrically bonded by wire bonding to the two first drain electrodes 111 of the first semiconductor element 11, the two second drain electrodes 121 of the second semiconductor element 12, and the first overhanging part 212 of the first lead 21. As viewed in the first direction z, the first conductive member 31 extends in the second direction x.

As shown in FIGS. 12 and 14, the second conductive member 32 is a plurality of wires. The second conductive member 32 is electrically bonded by wire bonding to the two first source electrodes 112 of the first semiconductor element 11, the two second source electrode 122 of the second semiconductor element 12, and the second overhanging part 222 of the second lead 22. As viewed in the first direction z, the second conductive member 32 extends in the second direction X.

The following describes the operation and effects of the semiconductor device A20.

A semiconductor device A20 includes: a first semiconductor element 11 that includes a first drain electrode 111 and a first source electrode 112; a second semiconductor element 12 that includes a second drain electrode 121 and a second source electrode 122; a first conductive member 31; and a second conductive member 32. The first conductive member 31 is electrically bonded to the first drain electrode 111 and the second drain electrode 121. The second conductive member 32 is electrically bonded to the first source electrode 112 and the second source electrode 122. As viewed in the first direction z, the first conductive member 31 and the second conductive member 32 each intersect a gap G existing between the first semiconductor element 11 and the second semiconductor element 12. This configuration enables the semiconductor device A20 to carry a larger electric current and improves the reliability of the semiconductor device A20. Additionally, the semiconductor device A20 has a configuration in common with the semiconductor device A10, thereby achieving the same effect as the semiconductor device A10.

For the semiconductor device A20, each of the first conductive member 31 and the second conductive member 32 includes wires. This configuration provides greater flexibility in the lengths of the conductive paths of the first conductive member 31 and the second conductive member 32, as compared with the configuration of the semiconductor device A10.

### Third Embodiment

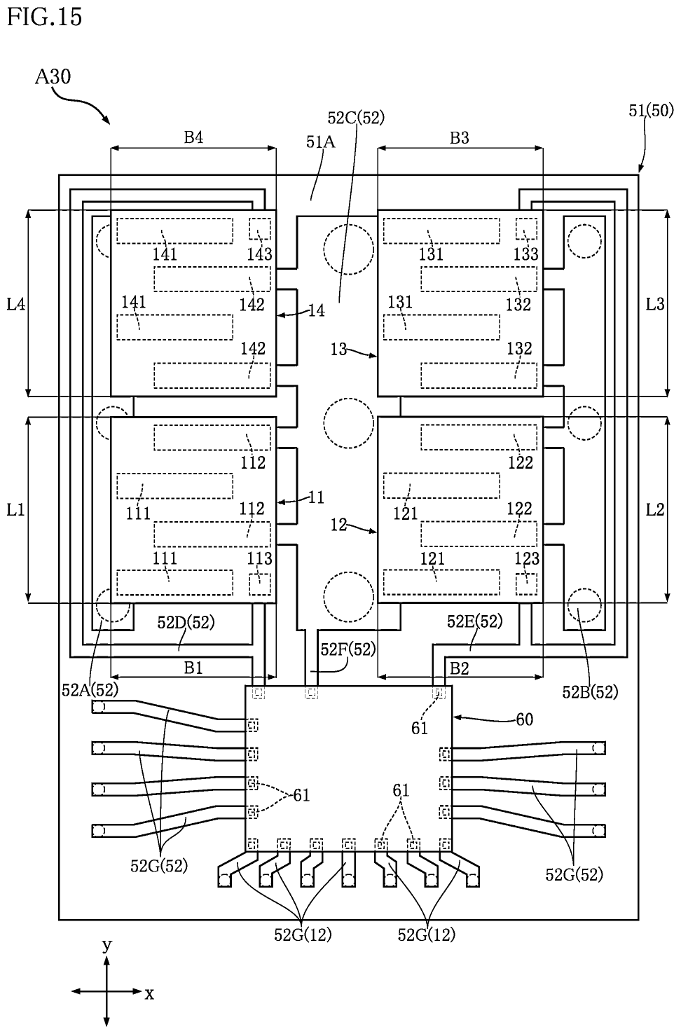

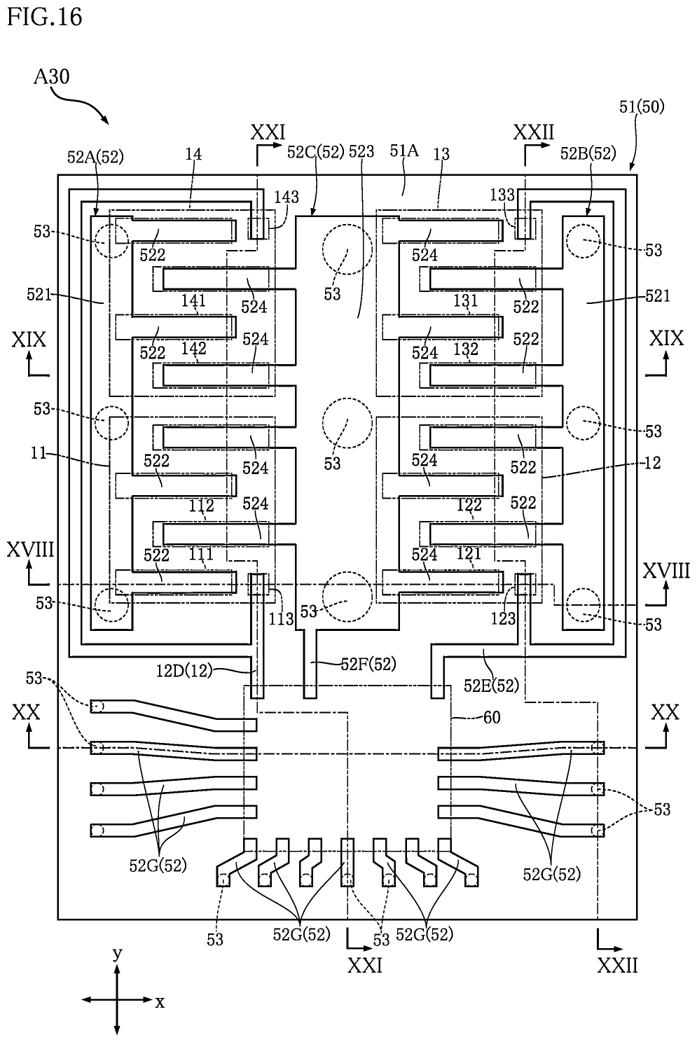

With reference to FIGS. 15 to 22, the following describes a semiconductor device A30 according to a third embodiment of the present disclosure. The semiconductor device A30 includes a first semiconductor element 11, a second semiconductor element 12, a third semiconductor element 13, a fourth semiconductor element 14, a bonding layer 19, a scaling resin 40, a supporting member 50, an IC 60, and a plurality of terminals 70. The semiconductor device A30 is a resin packaged device for surface mounting on a wiring board. The semiconductor device A30 receives DC power from an external source and converts the DC power into AC power using the first semiconductor element 11, the second semiconductor element 12, the third semiconductor element 13, and the fourth semiconductor element 14. The resulting AC power is supplied to a drive target, such as a motor. For the convenience of description, FIG. 15 omits the scaling resin 40. FIG. 16 is similar to FIG. 15, except that the first semiconductor element 11, the second semiconductor element 12, the third semiconductor element 13, the fourth semiconductor element 14, and the IC 60 are shown as transparent. In FIG. 16, the outlines of the first semiconductor element 11, the second semiconductor element 12, the third semiconductor element 13, the fourth semiconductor element 14, and the IC 60 are indicated with imaginary lines.

In the description of the semiconductor device A30, the direction of the normal to a mounting surface 51A of a substrate 51, which will be described later, is referred to as “first direction z”. A direction perpendicular to the first direction z is referred to as “second direction x”. The direction perpendicular to the first direction z and second direction x is referred to as “third direction y”. As shown in FIG. 15 the semiconductor device A30 is rectangular as viewed in the first direction z.

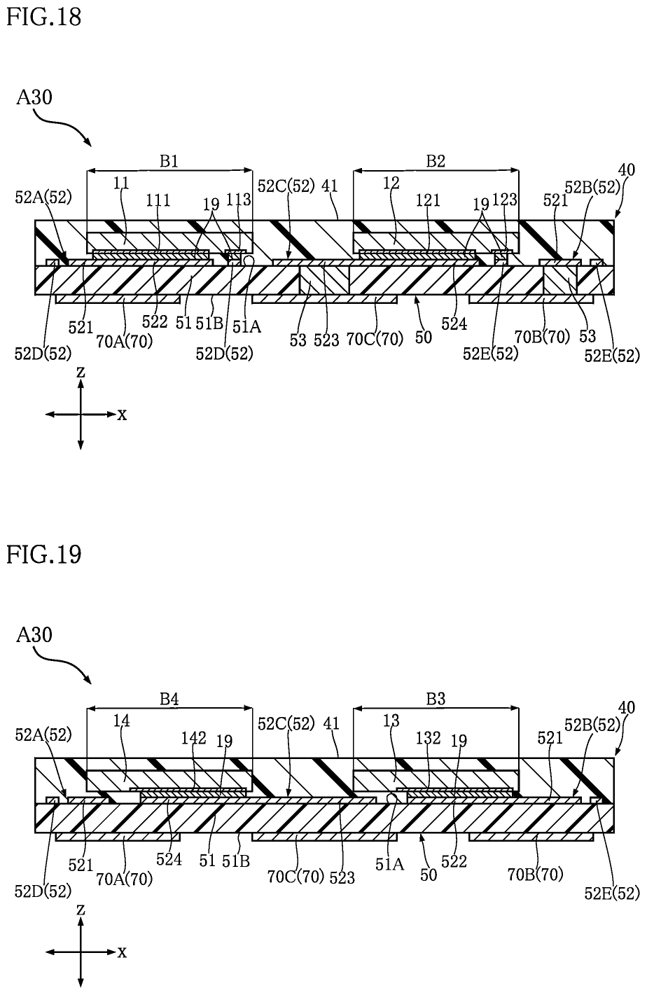

As shown in FIGS. 18 to 22, the supporting member 50 supports the first semiconductor element 11, the second semiconductor element 12, the third semiconductor element 13, the fourth semiconductor element 14, the IC 60, and the sealing resin 40. The supporting member 50 forms the conductive paths connecting the first semiconductor element 11, the second semiconductor element 12, the third semiconductor element 13, the fourth semiconductor element 14, and the IC 60 to a wiring board when the semiconductor device A30 is mounted on the wiring board. The supporting member 50 includes the substrate 51, a plurality of wirings 52, and a plurality of connecting wirings 53. In a different example, the supporting member 50 may include a plurality of conductive members made of metal (for example, a plurality of leads).

As shown in FIGS. 18 to 22, the substrate 51 supports the wirings 52, the connecting wirings 53, and the terminals 70. The substrate 51 is electrically insulating. The substrate 51 is made of a material containing resin. Examples of the resin include epoxy resin.

As shown in FIGS. 18 to 22, the substrate 51 has the mounting surface 51A and a reverse surface 51B. The mounting surface 51A faces in the first direction z. The reverse surface 51B faces away from the mounting surface 51A in the first direction z. The reverse surface 51B is exposed to the outside. When the semiconductor device A30 is mounted on a wiring board, the reverse surface 51B faces the wiring board.

As shown in FIGS. 18 and 19, the first semiconductor element 11, the second semiconductor element 12, the third semiconductor element 13, and the fourth semiconductor element 14 face the mounting surface 51A of the substrate 51. The first semiconductor element 11, the second semiconductor element 12, the third semiconductor element 13, and the fourth semiconductor element 14 are transistors (switching elements) mainly used for power conversion. The first semiconductor element 11, the second semiconductor element 12, the third semiconductor element 13, and the fourth semiconductor element 14 are made of a material containing a nitride semiconductor, for example. For the semiconductor device A30, the first semiconductor element 11, the second semiconductor element 12, the third semiconductor element 13, and the fourth semiconductor element 14 are high electron mobility transistors (HEMTs) made of a material containing gallium nitride.

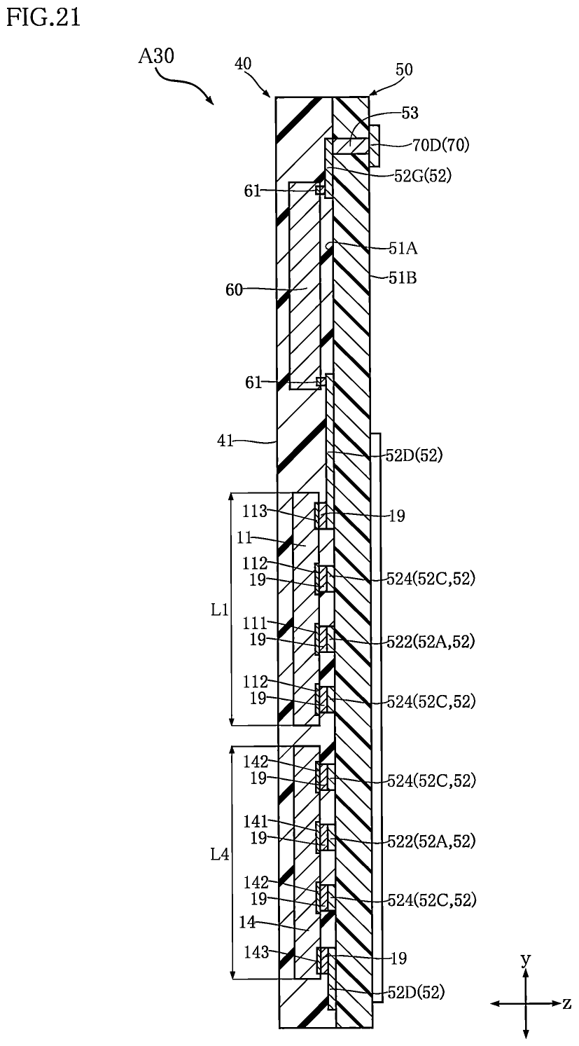

As shown in FIG. 15, the first semiconductor element 11 includes two first drain electrodes 111, two first source electrodes 112, and a first gate electrode 113. As shown in FIG. 21, the two first drain electrodes 111 and the two first source electrodes 112, and the first gate electrode 113 are located on the side facing the mounting surface 51A of the substrate 51 in the first direction z. The electric current corresponding to the power to be converted by the first semiconductor element 11 flows through the two first drain electrodes 111. The electric current corresponding to the power having been converted by the first semiconductor element 11 flows through the two first source electrodes 112. A gate voltage for driving the first semiconductor element 11 is applied to the first gate electrode 113. The first semiconductor element 11 has a dimension L1 in the third direction y and a dimension BI in the second direction x, where L1 is greater than B1. The two first drain electrodes 111 and the two first source electrodes 112 each extend in the second direction x.

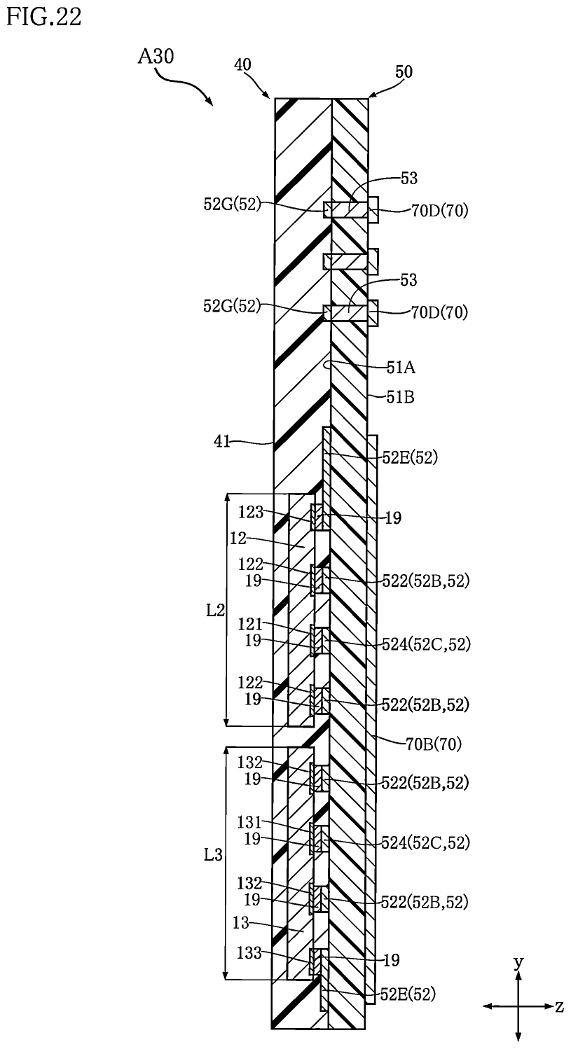

As shown in FIG. 15, the second semiconductor element 12 is adjacent to the first semiconductor element 11 in the second direction x. The second semiconductor element 12 includes two second drain electrodes 121, two second source electrodes 122, and a second gate electrode 123. As shown in FIG. 22, the two second drain electrodes 121 and the two second source electrodes 122, and the second gate electrode 123 are located on the side facing the mounting surface 51A of the substrate 51 in the first direction z. The electric current corresponding to the power to be converted by the second semiconductor element 12 flows through the two second drain electrodes 121. The electric current corresponding to the power having been converted by the second semiconductor element 12 flows through the two second source electrodes 122. A gate voltage for driving the second semiconductor element 12 is applied to the second gate electrode 123. The second semiconductor element 12 has a dimension L2 in the third direction y and a dimension B2 in the second direction x, where L2 is greater than B2. The two second drain electrodes 121 and the two second source electrodes 122 each extend in the second direction x.

As shown in FIG. 15, the third semiconductor element 13 is adjacent to the second semiconductor element 12 in the third direction y. The third semiconductor element 13 includes two third drain electrodes 131, two third source electrodes 132, and a third gate electrode 133.

As shown in FIG. 22, the two third drain electrodes 131 and the two third source electrodes 132, and the third gate electrode 133 are located on the side facing the mounting surface 51A of the substrate 51 in the first direction z. The electric current corresponding to the power to be converted by the third semiconductor element 13 flows through the two third drain electrodes 131. The electric current corresponding to the power having been converted by the third semiconductor element 13 flows through the two third source electrodes 132. A gate voltage for driving the third semiconductor element 13 is applied to the third gate electrode 133. The third semiconductor element 13 has a dimension L3 in the third direction y and a dimension B3 in the second direction x, where L3 is greater than B3. The two third drain electrodes 131 and the two third source electrodes 132 each extend in the second direction x.

As shown in FIG. 15, the fourth semiconductor element 14 is adjacent to the third semiconductor element 13 in the second direction x and to the first semiconductor element 11 in the third direction y. The fourth semiconductor element 14 includes two fourth drain electrodes 141, two fourth source electrodes 142, and a fourth gate electrode 143. As shown in FIG. 21, the two fourth drain electrodes 141 and the two fourth source electrodes 142, and the fourth gate electrode 143 are located on the side facing the mounting surface 51A of the substrate 51 in the first direction z. The electric current corresponding to the power to be converted by the fourth semiconductor element 14 flows through the two fourth drain electrodes 141. The electric current corresponding to the power having been converted by the fourth semiconductor element 14 flows through the two fourth source electrodes 142. A gate voltage for driving the fourth semiconductor element 14 is applied to the fourth gate electrode 143. The fourth semiconductor element 14 has a dimension L4 in the third direction y and a dimension B4 in the second direction x, where L4 is greater than B4. The two fourth drain electrodes 141 and the two fourth source electrodes 142 each extend in the second direction x.

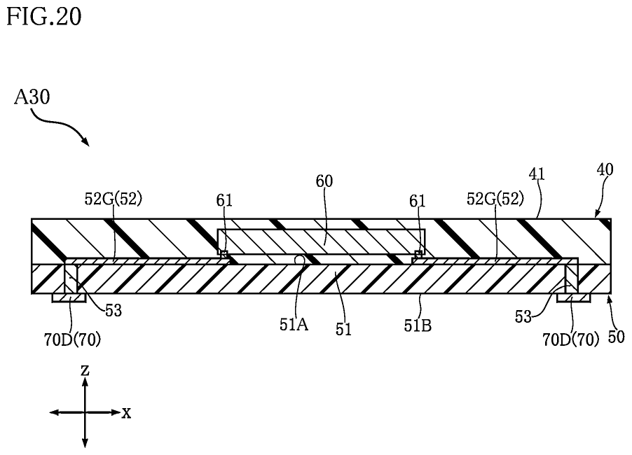

As shown in FIG. 20, the IC 60 faces the mounting surface 51A of the substrate 51. The IC 60 is a gate driver that applies a gate voltage to the first gate electrode 113, the second gate electrode 123, the third gate electrode 133, and the fourth gate electrode 143 of the first semiconductor element 11, the second semiconductor element 12, the third semiconductor element 13, and the fourth semiconductor element 14, respectively. The IC 60 includes a plurality of electrodes 61. The electrodes 61 face the mounting surface 51A.

As shown in FIGS. 16, and 18 to 22, the wirings 52 are disposed on the mounting surface 51A of the substrate 51. The composition of the wirings 52 includes copper (Cu), for example. The wirings 52 together with the connecting wirings 53 and the terminals 70 form the conductive paths connecting the first semiconductor element 11, the second semiconductor element 12, and the IC 60 to a wiring board when the semiconductor device A30 is mounted on the wiring board.

As shown in FIG. 16, the wirings 52 include a first wiring 52A, a second wiring 52B, a third wiring 52C, a first gate wiring 52D, a second gate wiring 52E, a potential wiring 52F, and a plurality of control wirings 52G.

As shown in FIG. 16, the first wiring 52A and the second wiring 52B are spaced apart from each other in the second direction x. The first wiring 52A and the second wiring 52B each includes a first base part 521 and a plurality of first extending parts 522. The first base part 521 extends in the third direction y. The first extending parts 522 extend from the first base part 521 in the second direction x toward a second base part 523 of the third wiring 52C, which will be described later. The first extending parts 522 are arranged next to each other in the third direction y.

As shown in FIG. 21, the two first drain electrodes 111 of the first semiconductor element 11 and the two fourth drain electrodes 141 of the fourth semiconductor element 14 are each electrically bonded to one of the first extending parts 522 of the first wiring 52A via the bonding layer 19. As shown in FIG. 22, the two second source electrode 122 of the second semiconductor element 12 and the two third source electrodes 132 of the third semiconductor element 13 are each electrically bonded to one of the first extending parts 522 of the second wiring 52B via the bonding layer 19.

As shown in FIG. 16, the third wiring 52C is located between the first base part 521 of the first wiring 52A and the first base part 521 of the second wiring 52B in the second direction x. The third wiring 52C includes a second base part 523 and a plurality of second extending parts 524. The second base part 523 extends in the third direction y. The plurality of second extending parts 524 each extend in the second direction x from either end of the second base part 523 in the second direction x, including those extending toward the first base part 521 of the first wiring 52A and those extending toward the first base part 521 of the second wiring 52B. The second extending parts 524 are arranged next to each other in the third direction y.

As shown in FIG. 21, the two first source electrodes 112 of the first semiconductor element 11 and the two fourth source electrodes 142 of the fourth semiconductor element 14 are each electrically bonded to one of the second extending parts 524 via the bonding layer 19. As shown in FIG. 22, the two second drain electrodes 121 of the second semiconductor element 12 and the two third drain electrodes 131 of the third semiconductor element 13 are each electrically bonded to one of the second extending parts 524 via the bonding layer 19. Thus, the two second drain electrodes 121 of second semiconductor element 12 and the two third drain electrodes 131 of the third semiconductor element 13 are electrically connected to the two first source electrodes 112 of the first semiconductor element 11 and the two fourth source electrodes 142 of the fourth semiconductor element 14.

As shown in FIG. 21, the first gate electrode 113 of the first semiconductor element 11 and the fourth gate electrode 143 of the fourth semiconductor element 14 are electrically bonded to the first gate wiring 52D via the bonding layer 19. As shown in FIG. 22, the second gate electrode 123 of the second semiconductor element 12 and the third gate electrode 133 of the third semiconductor element 13 are electrically bonded to the second gate wiring 52E via the bonding layer 19.

As shown in FIGS. 15 and 16, the potential wiring 52F is connected to the second base part 523 of the third wiring 52C. The potential wiring 52F is used by the IC 60 to establish a ground for the gate voltage applied to the first gate electrode 113 of the first semiconductor element 11 and the fourth gate electrode 143 of the fourth semiconductor element 14.

As shown in FIGS. 15, 20, and 21, the plurality of electrodes 61 of the IC 60 are each electrically bonded to one of the first gate wiring 52D, the second gate wiring 52E, the potential wiring 52F, and the control wirings 52G. The IC 60 is thus electrically connected to the first gate electrode 113 of the first semiconductor element 11, the second gate electrode 123 of the second semiconductor element 12, the third gate electrode 133 of the third semiconductor element 13, the fourth gate electrode 143 of the fourth semiconductor element 14, and the third wiring 52C.

As shown in FIGS. 18, and 20 to 22, the connecting wirings 53 are embedded in the substrate 51. The ends of each connecting wiring 53 in the first direction z are exposed from the mounting surface 51A and the reverse surface 51B of the substrate 51. Each connecting wiring 53 is connected to one of the wirings 52 other than the first gate wiring 52D, and the second gate wiring 52E. Each connecting wiring 53 is also connected to one of the terminals 70. Thus, each terminal 70 is electrically connected to one of the first wiring 52A, the second wiring 52B, the third wiring 52C, and the control wirings 52G among the plurality of wirings 52. The composition of the connecting wirings 53 includes copper, for example.

As shown in FIGS. 18 to 22, the sealing resin 40 covers the first semiconductor element 11, the second semiconductor element 12, the third semiconductor element 13, the fourth semiconductor element 14, the IC 60, and the wiring 52. The sealing resin 40 has a top surface 41 facing the same side as the mounting surface 51A of the substrate 51 in the first direction z.

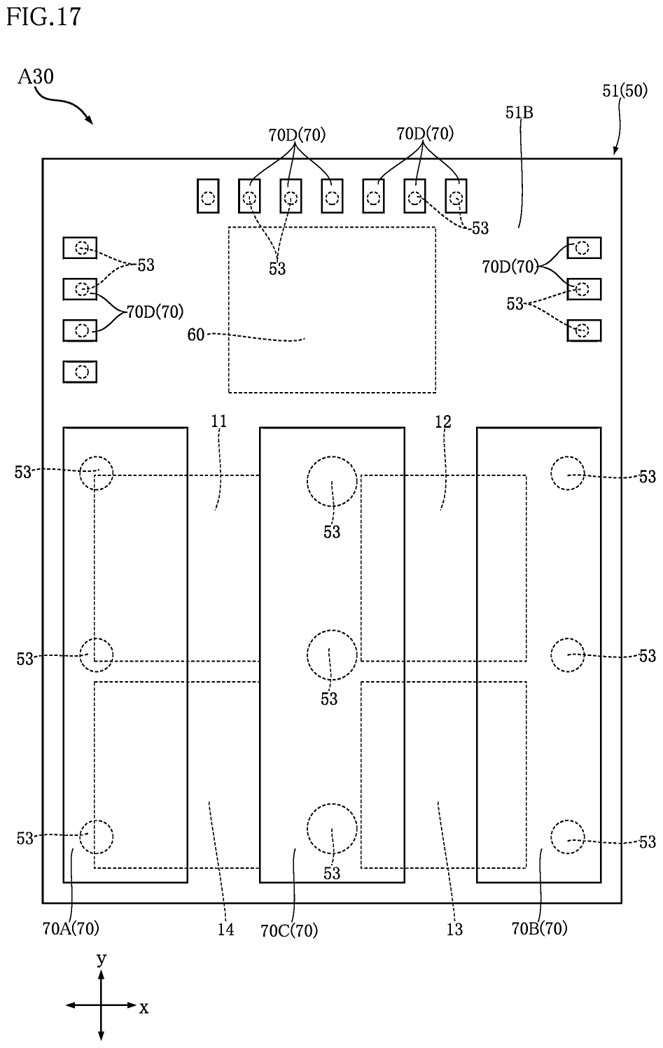

As shown in FIGS. 17 to 22, the terminals 70 are disposed on the reverse surface 51B of the substrate 51. The semiconductor device A30 is mounted on a wiring board by electrically bonding the terminals 70 to the wiring board with solder. The plurality of terminals 70 include a plurality of metal layers. The metal layers include a nickel layer and a gold (Au) layer that are stacked in sequence on the reverse surface 51B. In a different example, the plurality of metal layers may include a nickel layer, a palladium (Pd) layer, and a gold layer that are stacked in sequence on the reverse surface 51B.

As shown in FIG. 17, the plurality of terminals 70 include a first power terminal 70A, a second power terminal 70B, a third power terminal 70C, and a plurality of control terminals 70D.

The first power terminal 70A is electrically connected to the first wiring 52A. The second power terminal 70B is electrically connected to the second wiring 52B. The first power terminal 70A and the second power terminal 70B receive DC power to be converted by the first semiconductor element 11, the second semiconductor element 12, the third semiconductor element 13, and the fourth semiconductor element 14. The first power terminal 70A is a positive terminal (P terminal). The second power terminal 70B is a negative terminal (N terminal).

The third power terminal 70C is electrically connected to the third wiring 52C. The third power terminal 70C outputs the AC power having been converted by the first semiconductor element 11, the second semiconductor element 12, the third semiconductor element 13, and the fourth semiconductor element 14.

The control terminals 70D are electrically connected to the IC 60 via the control wirings 52G. One of the control terminals 70D is for receiving power for driving the IC 60. One of the control terminals 70D is for receiving an electrical signal directed to the IC 60. One of the control terminals 70D is for outputting an electrical signal from the IC 60.

The following describes the operation and effects of the semiconductor device A30.

A semiconductor device A30 includes: a first semiconductor element 11 that includes a first drain electrode 111 and a first source electrode 112; a second semiconductor element 12 that includes a second drain electrode 121 and a second source electrode 122; and a third semiconductor element 13 that includes a third drain electrode 131 and a third source electrode 132. The semiconductor device A30 also includes: a first wiring 52A to which the first drain electrode 111 is electrically bonded, a second wiring 52B to which the second source electrode 122 and the third source electrode 132 are electrically bonded; and a third wiring 52C to which the first source electrode 112, the second drain electrode 121, and the third drain electrode 131 are electrically bonded. The second semiconductor element 12 is adjacent to the first semiconductor element 11 in the second direction x. The third semiconductor element 13 is adjacent to the second semiconductor element 12 in the third direction y.

With this configuration, the semiconductor device A30 includes a half-bridge circuit, with the first semiconductor element 11 forming an upper arm, and the second semiconductor element 12 and the third semiconductor element 13 forming a lower arm. In this case, the second drain electrode 121 and the third drain electrode 131 are connected in parallel to the third wiring 52C. Additionally, the second source electrode 122 and the third source electrode 132 are connected in parallel to the second wiring 52B. This enables the semiconductor device A30 to carry a larger electric current. In addition, even if the function of the second semiconductor element 12 degrades, the semiconductor device A30 remains operational as long as the third semiconductor element 13 functions normally. The semiconductor device A30 is thus capable of carrying a larger electric current, while ensuring greater reliability.

Note that the semiconductor device A30 may be configured without the fourth semiconductor element 14. The semiconductor device A30 in this example can still improve the reliability of the lower arm.

The semiconductor device A30 also includes a plurality of terminals 70 electrically connected to the wirings 52. The terminals 70 are located on the side opposite the wirings 52 in the first direction z with respect to the substrate 51. With this configuration, the wirings 52 are entirely covered with the sealing resin 40 but still provide a conductive path to a wiring board when the semiconductor device A30 is mounted on the wiring board. This is achieved without upsizing the semiconductor device A30.

The present disclosure is not limited to the embodiments described above. Various modifications in design may be made freely in the specific structure of each part according to the present disclosure.

The present disclosure includes the embodiments described in the following clauses. Clause 1.

A semiconductor device comprising:
a first semiconductor element including a first drain electrode and a first source electrode on a first side in a first direction;
a second semiconductor element including a second drain electrode and a second source electrode on the first side in the first direction, the second semiconductor element being next to the first semiconductor element in a second direction perpendicular to the first direction;
a first conductive member electrically bonded to the first drain electrode and the second drain electrode; and
a second conductive member electrically bonded to the first source electrode and the second source electrode,
wherein the first conductive member and the second conductive member each intersect a gap between the first semiconductor element and the second semiconductor element as viewed in the first direction.

Clause 2.

The semiconductor device according to Clause 1, wherein the second drain electrode is next to the first drain electrode in the second direction, and the second source electrode is next to the first source electrode in the second direction.

Clause 3.

The semiconductor device according to Clause 2, wherein the first conductive member includes a first base part and a first bonding part that are connected to the first base part,
the first base part is located on a side opposite the first semiconductor element in the second direction with respect to the second semiconductor element,
the first bonding part extends in the second direction as viewed in the first direction, and
the first drain electrode and the second drain electrode are electrically bonded to the first bonding part.

Clause 4.

The semiconductor device according to Clause 3, wherein the second conductive member includes a second base part and a second bonding part that are connected to the second base part,
the second base part is located on a side opposite the first base part in the second direction with respect to the first semiconductor element and the second semiconductor element,
the second bonding part extends in the second direction as viewed in the first direction, and
the first source electrode and the second source electrode are electrically bonded to the second bonding part.

Clause 5.

The semiconductor device according to Clause 4, wherein the first source electrode is next to the first drain electrode in a third direction perpendicular to the first direction and the second direction, and
the second source electrode is next to the second drain electrode in the third direction.

Clause 6.

The semiconductor device according to Clause 2, wherein the first conductive member and the second conductive member each include a wire, and
the first conductive member and the second conductive member each extend in the second direction as viewed in the first direction.

Clause 7.

The semiconductor device according to Clause 5, wherein the first semiconductor element includes a first gate electrode on a same side as the first drain electrode and the first source electrode in the first direction,
the second semiconductor element includes a second gate electrode on a same side as the second drain electrode and the second source electrode in the first direction,
the semiconductor device further comprises a third conductive member electrically connected to the first gate electrode and the second gate electrode, and
the third conductive member intersects the gap as viewed in the first direction.

Clause 8.

The semiconductor device according to Clause 7, wherein the second gate electrode is next to the first gate electrode in the second direction, and
the third conductive member extends in the second direction as viewed in the first direction.

Clause 9.

The semiconductor device according to Clause 8, wherein the third conductive member is spaced apart from the first drain electrode and the second drain electrode as viewed in the first direction.

Clause 10.

The semiconductor device according to Clause 9, wherein the third conductive member is spaced apart from the first conductive member and the second conductive member as viewed in the first direction.

Clause 11.

The semiconductor device according to any one of Clauses 7 to 10, further comprising a first lead and a second lead that are spaced apart from each other in the second direction,
the first base part is electrically bonded to the first lead, and
the second base part is electrically bonded to the second lead.

Clause 12.

The semiconductor device according to Clause 11, further comprising a die pad between the first lead and the second lead in the second direction,
wherein the first semiconductor element and the second semiconductor element are bonded to the die pad.

Clause 13.

The semiconductor device according to Clause 12, further comprising a third lead next to the second lead in the third direction,
wherein the third conductive member is electrically bonded to the third lead.

Clause 14.

The semiconductor device according to Clause 13, further comprising a sealing resin covering the first semiconductor element and the second semiconductor element,
wherein the sealing resin includes a bottom surface facing a side opposite the first semiconductor element and the second semiconductor element in the first direction with respect to the die pad, and
the first lead, the second lead, the third lead, and the die pad are each exposed from the bottom surface.

Clause 15.

The semiconductor device according to Clause 14, wherein the sealing resin includes a first side surface and a second side surface facing away from each other in the second direction, and
the first lead, the second lead, and the third lead are each exposed from either the first side surface or the second side surface.

Clause 16.

A semiconductor device comprising:
a first semiconductor element including a first drain electrode and a first source electrode disposed on a first side in a first direction;
a second semiconductor element including a second drain electrode and a second source electrode disposed on the first side in the first direction;
a third semiconductor element including a third drain electrode and a third source electrode disposed on the first side in the first direction;
a first wiring to which the first drain electrode is electrically bonded;
a second wiring to which the second source electrode and the third source electrode are electrically bonded; and
a third wiring to which the first source electrode, the second drain electrode, and the third drain electrode are electrically bonded,
wherein the second semiconductor element is next to the first semiconductor element in a second direction perpendicular to the first direction, and
the third semiconductor element is next to the second semiconductor element in a third direction perpendicular to the first direction and the second direction.

Clause 17.

The semiconductor device according to Clause 16, wherein a dimension of the first semiconductor element in the third direction is greater than a dimension of the first semiconductor element in the second direction, and
a dimension of the second semiconductor element in the third direction is greater than a dimension of the second semiconductor element in the second direction.

Clause 18.

The semiconductor device according to Clause 17, wherein a dimension of the third semiconductor element in the third direction is greater than a dimension of the third semiconductor element in the second direction.

### Reference Numerals

| | | |
|---|---|---|
| A10, A20, A30: semiconductor device | | |
| 11: first semiconductor element | | |
| 111: first drain electrode | 112: first source electrode | |
| 113: first gate electrode | 12: second semiconductor element | |
| 121: second drain electrode | 122: second source electrode | |
| 123: second gate electrode | 13: third semiconductor element | |
| 131: third drain electrode | 132: third source electrode | |
| 133: third gate electrode | 14: fourth semiconductor element | |
| 141: fourth drain electrode | 142: fourth source electrode | |
| 143: fourth gate electrode | 19: bonding layer | |
| 20: die pad | 20A: mounting surface | |
| 20B: reverse surface | 201: mounting part | |
| 202: overhanging part | 203: suspending part | |
| 203A: end surface | 21: first lead | |
| 211: first terminal part | 211A: mounting surface | |
| 211B: side surface | 212: first overhanging part | |
| 22: second lead | 221: second terminal part | |
| 221A: mounting surface | 221B: side surface | |
| 222: second overhanging part | 223: coupling part | |
| 23: third lead | 231: third terminal part | |
| 231A: mounting surface | 231B: side surface | |
| 232: third overhanging part | 31: first conductive member | |
| 311: first base part | 311A: through-hole | |
| 312: first connecting part | 313: suspending part | |
| 313A: end surface | 32: second conductive member | |
| 321: second base part | 321A: through-hole | |
| 322: second connecting part | 323: suspending part | |
| 323A: end surface | 324: arm part | |
| 324A: end surface | 33: third conductive member | |
| 39: bonding layer | 40: sealing resin | |
| 41: top surface | 42: bottom surface | |
| 43: first side surface | 44: second side surface | |
| 45: third side surface | 50: supporting member | |
| 51: substrate | 51A: mounting surface | |
| 51B: reverse surface | 52: wiring | |
| 521: first base part | 522: first extending part | |
| 523: second base part | 524: second extending part | |
| 52A: first wiring | 52B: second wiring | |
| 52C: third wiring | 52D: first gate wiring | |
| 52E: second gate wiring | 52F: potential wiring | |
| 52G: control wiring | 53: connecting wiring | |
| 60: IC | 61: electrode | |
| 70: terminal | 70A: first power terminal | |
| 70B: second power terminal | 70C: third power terminal | |
| 70D: control terminal | G: gap | |
| z: first direction | x: second direction | y: third direction |

1. A semiconductor device comprising:
a first semiconductor element including a first drain electrode and a first source electrode on a first side in a first direction;
a second semiconductor element including a second drain electrode and a second source electrode on the first side in the first direction, the second semiconductor element being next to the first semiconductor element in a second direction perpendicular to the first direction;
a first conductive member electrically bonded to the first drain electrode and the second drain electrode; and
a second conductive member electrically bonded to the first source electrode and the second source electrode,
wherein the first conductive member and the second conductive member each intersect a gap between the first semiconductor element and the second semiconductor element as viewed in the first direction.

2. The semiconductor device according to claim 1, wherein the second drain electrode is next to the first drain electrode in the second direction, and
the second source electrode is next to the first source electrode in the second direction.

3. The semiconductor device according to claim 2, wherein the first conductive member includes a first base part and a first bonding part that are connected to the first base part,
the first base part is located on a side opposite the first semiconductor element in the second direction with respect to the second semiconductor element,
the first bonding part extends in the second direction as viewed in the first direction, and
the first drain electrode and the second drain electrode are electrically bonded to the first bonding part.

4. The semiconductor device according to claim 3, wherein the second conductive member includes a second base part and a second bonding part that are connected to the second base part,
the second base part is located on a side opposite the first base part in the second direction with respect to the first semiconductor element and the second semiconductor element,
the second bonding part extends in the second direction as viewed in the first direction, and
the first source electrode and the second source electrode are electrically bonded to the second bonding part.

5. The semiconductor device according to claim 4, wherein the first source electrode is next to the first drain electrode in a third direction perpendicular to the first direction and the second direction, and
the second source electrode is next to the second drain electrode in the third direction.

6. The semiconductor device according to claim 2, wherein the first conductive member and the second conductive member each include a wire, and
the first conductive member and the second conductive member each extend in the second direction as viewed in the first direction.

7. The semiconductor device according to claim 5, wherein the first semiconductor element includes a first gate electrode on a same side as the first drain electrode and the first source electrode in the first direction,
the second semiconductor element includes a second gate electrode on a same side as the second drain electrode and the second source electrode in the first direction,
the semiconductor device further comprises a third conductive member electrically connected to the first gate electrode and the second gate electrode, and
the third conductive member intersects the gap as viewed in the first direction.

8. The semiconductor device according to claim 7, wherein the second gate electrode is next to the first gate electrode in the second direction, and
the third conductive member extends in the second direction as viewed in the first direction.

9. The semiconductor device according to claim 8, wherein the third conductive member is spaced apart from the first drain electrode and the second drain electrode as viewed in the first direction.

10. The semiconductor device according to claim 9, wherein the third conductive member is spaced apart from the first conductive member and the second conductive member as viewed in the first direction.

11. The semiconductor device according to claim 7, further comprising a first lead and a second lead that are spaced apart from each other in the second direction,
the first base part is electrically bonded to the first lead, and
the second base part is electrically bonded to the second lead.

12. The semiconductor device according to claim 11, further comprising a die pad between the first lead and the second lead in the second direction,
wherein the first semiconductor element and the second semiconductor element are bonded to the die pad.

13. The semiconductor device according to claim 12, further comprising a third lead next to the second lead in the third direction,
wherein the third conductive member is electrically bonded to the third lead.

14. The semiconductor device according to claim 13, further comprising a sealing resin covering the first semiconductor element and the second semiconductor element,
wherein the sealing resin includes a bottom surface facing a side opposite the first semiconductor element and the second semiconductor element in the first direction with respect to the die pad, and
the first lead, the second lead, the third lead, and the die pad are each exposed from the bottom surface.

15. The semiconductor device according to claim 14, wherein the sealing resin includes a first side surface and a second side surface facing away from each other in the second direction, and
the first lead, the second lead, and the third lead are each exposed from either the first side surface or the second side surface.

16. A semiconductor device comprising:
a first semiconductor element including a first drain electrode and a first source electrode disposed on a first side in a first direction;
a second semiconductor element including a second drain electrode and a second source electrode disposed on the first side in the first direction;
a third semiconductor element including a third drain electrode and a third source electrode disposed on the first side in the first direction;
a first wiring to which the first drain electrode is electrically bonded;
a second wiring to which the second source electrode and the third source electrode are electrically bonded; and
a third wiring to which the first source electrode, the second drain electrode, and the third drain electrode are electrically bonded,
wherein the second semiconductor element is next to the first semiconductor element in a second direction perpendicular to the first direction, and
the third semiconductor element is next to the second semiconductor element in a third direction perpendicular to the first direction and the second direction.

17. The semiconductor device according to claim 16, wherein a dimension of the first semiconductor element in the third direction is greater than a dimension of the first semiconductor element in the second direction, and
a dimension of the second semiconductor element in the third direction is greater than a dimension of the second semiconductor element in the second direction.

18. The semiconductor device according to claim 17, wherein a dimension of the third semiconductor element in the third direction is greater than a dimension of the third semiconductor element in the second direction.
